(19) United States
(12) Patent Application Publication
(10) Pub. No.: US 2025/0176382 A1
(43) Pub. Date: May 29, 2025

(54) DISPLAY SUBSTRATE AND DISPLAY APPARATUS

(71) Applicants: Chengdu BOE Optoelectronics Technology Co., Ltd., Chengdu, Sichuan (CN); BOE Technology Group Co., Ltd., Beijing (CN)

(72) Inventors: Yi HE, Beijing (CN); Rong WANG, Beijing (CN); Jun YAN, Beijing (CN); Fan HE, Beijing (CN); Xiangdan DONG, Beijing (CN); Hui GUAN, Beijing (CN); Hanchao LI, Beijing (CN)

(21) Appl. No.: 18/839,735

(22) PCT Filed: Nov. 10, 2023
(86) PCT No.: PCT/CN2023/130945

§ 371 Date: Aug. 20, 2024

(30) Foreign Application Priority Data
Dec. 23, 2022 (CN) 202211667821.1

(51) Int. Cl. H10K 59/131

(52) U.S. Cl. CPC H10K 59/131

(57) ABSTRACT

A display substrate, comprising a substrate, a plurality of first circuit groups, at least one group of first connecting lines, and at least one group of second connecting lines. The substrate comprises a display area, and a binding area, which is located on one side of the display area. The plurality of first circuit groups, the at least one group of first connecting lines and the at least one group of second connecting lines are located in the binding area. The plurality of first circuit groups are arranged in a first direction. At least two adjacent first circuit groups-among the plurality of first circuit groups are electrically connected by means of one group of first connecting lines and one group of second connecting lines. In one group of first connecting lines and one group of second connecting lines, a first connecting line and a second connecting line, which transmit the same signal, are connected in parallel, and the at least one group of second connecting lines is located on the side of the at least one group of first connecting lines that is close to the display area.

### CROSS-REFERENCE TO RELATED APPLICATIONS

The present application is a U.S. National Phase Entry of International Application No. PCT/CN2023/130945 having an international filing date of Nov. 10, 2023, which claims priority of Chinese Patent Application No. 202211667821.1, filed on Dec. 23, 2022, to the China National Intellectual Property Administration, which are hereby incorporated herein by reference in their entireties.

### TECHNICAL FIELD

The present disclosure relates to, but is not limited to, the field of display technologies, in particular to a display substrate and a display apparatus.

### BACKGROUND

An Organic Light Emitting Diode (OLED) and a Quantum-dot Light Emitting Diode (QLED) are active light emitting display devices and have advantages of self-luminescence, a wide viewing angle, a high contrast ratio, low power consumption, an extremely high response speed, lightness and thinness, bendability, and a low cost, etc.

### SUMMARY

The following is a summary of subject matters described herein in detail. This summary is not intended to limit the protection scope of claims.

Embodiments of the present disclosure provide a display substrate and a display apparatus.

In one aspect, the present embodiment provides a display substrate including a base substrate, a plurality of first circuit groups, at least one group of first connection lines, and at least one group of second connection lines. The base substrate includes a display region and a bonding region on one side of the display region. The plurality of first circuit groups, the at least one group of first connection lines, and the at least one group of second connection lines are located in the bonding region. The plurality of first circuit groups are arranged along a first direction. At least two adjacent first circuit groups of the plurality of first circuit groups are electrically connected by a group of first connection lines and a group of second connection lines. A first connection line and a second connection line, in a group of first connection lines and a group of second connection lines, transmitting a same signal are connected in parallel, and the at least one group of second connection lines is located on a side of the at least one group of first connection lines close to the display region.

In some exemplary implementations, two adjacent first circuit groups of the plurality of first circuit groups are electrically connected by a group of first connection lines and a group of second connection lines.

In some exemplary implementations,, any two adjacent first circuit groups of the plurality of first circuit groups are electrically connected by a group of first connection lines and a group of second connection lines.

In some exemplary implementations, the bonding region includes a first sub-region, a bending region, and a second sub-region that are sequentially disposed in a direction away from the display region. The plurality of first circuit groups and the at least one group of first connection lines are located in the second sub-region, and the at least one group of second connection lines is located in the first sub-region.

In some exemplary implementations, the bending region includes a plurality of bending adapter lines, and two ends of each second connection line in a group of second connection lines are each electrically connected to a first connection line in a corresponding group of first connection lines via a bending adapter line.

In some exemplary implementations, in a direction perpendicular to the display substrate, the plurality of bending adapter lines are located on a side of the at least one group of first connection lines and the at least one group of second connection lines away from the base substrate.

In some exemplary implementations, the first sub-region further includes a plurality groups of first fan-out traces arranged along the first direction; a group of second connection lines is disposed between two adjacent groups of first fan-out traces, and an orthographic projection of the group of second connection lines on the base substrate does not overlap with orthographic projections of the two adjacent groups of first fan-out traces on the base substrate.

In some exemplary implementations, at least one first connection line in a group of first connection lines includes a first trace segment, a second trace segment, and a third trace segment that are electrically connected sequentially, the second trace segment extends in the first direction, the first trace segment is electrically connected to a first circuit group, and the third trace segment is electrically connected to another first circuit group.

In some exemplary implementations, the second sub-region further includes a plurality of first electrostatic discharge circuits; the first trace segment, the second trace segment and the third trace segment of at least one first connection line in the at least one group of first connection lines are each electrically connected to a first electrostatic discharge circuit; a first electrostatic discharge circuit to which the first trace segment is electrically connected is located on a side of the first trace segment close to the third trace segment, a first electrostatic discharge circuit to which the second trace segment is electrically connected is located on a side of the second trace segment close to the bending region, and a first electrostatic discharge circuit to which the third trace segment is electrically connected is located on a side of the third trace segment close to the first trace segment.

In some exemplary implementations, at least one second connection line in a group of second connection lines includes a fourth trace segment, a fifth trace segment, and a sixth trace segment that are electrically connected sequentially, the fifth trace segment extends in the first direction, the fourth and sixth trace segments are located on a side of the fifth trace segment away from the display region, and a length of the fifth trace segment along the first direction is less than a shortest distance between a first trace segment and a third trace segment of a first connection line to which the second connection line is electrically connected.

In some exemplary implementations, the display substrate further includes a buffer layer on a side of the base substrate away from the plurality of first circuit groups; an orthographic projection of the at least one group of first connection lines to which the at least one group of second connection lines are electrically connected on the base substrate partially overlaps with an orthographic projection of the buffer layer on the base substrate.

In some exemplary implementations, the display substrate further includes a plurality of bonding pin groups located in the bonding region, the plurality of bonding pin groups are located on a side of the plurality of first circuit groups away from the display region, and are electrically connected to the plurality of first circuit groups.

In some exemplary implementations, the display substrate further includes a plurality of drive chip pin groups located in the bonding region, the plurality of drive chip pin groups are located on a side of the plurality of first circuit groups away from the display region, and located on a side of the plurality of bonding pin groups close to the display region.

In some exemplary implementations, the display region includes a plurality of sub-pixels and a plurality of data lines electrically connected to the plurality of sub-pixels. At least one first circuit group of the plurality of first circuit groups includes a plurality of test circuits connected to the plurality of data lines and configured to provide test data signals to the plurality of data lines during a test phase.

In another aspect, a display apparatus is provided in an embodiment of the present disclosure, which includes the aforementioned display substrate.

Other aspects of the present disclosure may be comprehended after the drawings and the detailed descriptions are read and understood.

### BRIEF DESCRIPTION OF DRAWINGS

Accompanying drawings are used for providing further understanding of technical solutions of the present disclosure, constitute a portion of the specification, and are used for explaining the technical solutions of the present disclosure together with embodiments of the present disclosure, but do not constitute limitations on the technical solutions of the present disclosure. Shapes and sizes of one or more components in the drawings do not reflect actual scales, and are only intended to schematically describe contents of the present disclosure.

FIG. 1 is a schematic diagram of a structure of a display apparatus.

FIG. 2 is a schematic plan view of a display substrate.

FIG. 3 is a schematic diagram of a partial sectional structure of a display region of a display substrate.

FIG. 4 is a schematic diagram of a bonding region of a display substrate.

FIG. 5 is a schematic diagram of a display substrate after the bending process is performed.

FIG. 6 is a schematic diagram of a bonding region of a display substrate according to at least one embodiment of the present disclosure.

FIG. 7A is an example diagram of a bonding region of a display substrate according to at least one embodiment of the present disclosure.

FIG. 7B is a schematic partial diagram of the bonding region in FIG. 7A.

FIG. 8 is a schematic partial diagram of a bonding region according to at least one embodiment of the present disclosure.

FIG. 9 is an equivalent circuit diagram of a test circuit according to at least one embodiment of the present disclosure.

FIG. 10 is a schematic plan view of a test circuit according to at least one embodiment of the present disclosure.

FIG. 11 is a schematic diagram of a connection position between a first circuit group and a group of first connection lines according to at least one embodiment of the present disclosure.

FIG. 12 is a partial enlarged view of a region U1 in FIG. 11.

FIG. 13 is a schematic diagram of a connection position between a first trace segment and a second trace segment of a first connection line according to at least one embodiment of the present disclosure.

FIG. 14 is a schematic diagram of a connection position between a fourth trace segment of a second connection line and a bending connection line according to at least one embodiment of the present disclosure.

FIG. 15A is a schematic diagram of a first gate metal layer in FIG. 14.

FIG. 15B is a schematic diagram of a second gate metal layer in FIG. 14.

FIG. 16 is another schematic diagram of a bonding region of a display substrate according to at least one embodiment of the present disclosure.

### DETAILED DESCRIPTION

The embodiments of the present disclosure will be described below with reference to the drawings in detail. Implementation modes may be implemented in a plurality of different forms. Those of ordinary skills in the art may easily understand such a fact that implementations and contents may be transformed into other forms without departing from the purpose and scope of the present disclosure. Therefore, the present disclosure should not be explained as being limited to the contents recorded in the following implementations only. The embodiments and features in the embodiments of the present disclosure may be randomly combined with each other if there is no conflict.

In the drawings, a size of one or more constituent elements, a thickness of a layer, or a region is sometimes exaggerated for clarity. Therefore, one implementation of the present disclosure is not necessarily limited to the size, and a shape and a size of one or more components in the drawings do not reflect an actual scale. In addition, the accompanying drawings schematically illustrate ideal examples, and an implementation of the present disclosure is not limited to shapes, numerical values, or the like shown in the drawings.

Ordinal numerals “first”, “second”, “third”, etc., in the specification are set not to form limits in numbers but only to avoid confusion between composition elements. In the present disclosure, “plurality” represents two or more than two.

In the specification, for convenience, expressions “central”, “above”, “below”, “front”, “back”, “vertical”, “horizontal”, “top”, “bottom”, “inside”, “outside”, etc., indicating directional or positional relationships are used to illustrate positional relationships between the composition elements with reference to drawings, not to indicate or imply that involved devices or elements are required to have specific orientations and be structured and operated with the specific orientations but only to easily and simply describe the present specification, and thus should not be understood as limitations on the present disclosure. The positional relationships between the constituent elements are changed as appropriate according to a direction where the constituent elements are described. Therefore, appropriate replacements based on situations are allowed, which is not limited to the expressions in the specification.

In the specification, unless otherwise specified and defined, terms “mounting”, “mutual connection”, and “connection” should be understood in a broad sense. For example, it may be a fixed connection, a detachable connection, or an integral connection; it may be a mechanical connection or a connection; it may be a direct connection, an indirect connection through a middleware, or an internal communication inside two elements. Those of ordinary skills in the art may understand meanings of the aforementioned terms in the present disclosure according to situations.

In the specification, “electrical connection” includes connection of composition elements through an element with a certain electrical action. The “element with a certain electrical action” is not particularly limited as long as electrical signals between the connected constituent elements may be transmitted. Examples of the “element with a certain electrical action” not only include an electrode and a wiring, but also include a switching element such as a transistor, a resistor, an inductor, a capacitor, another element with a plurality of functions, etc.

In the specification, a transistor refers to an element which at least includes three terminals, i.e., a gate electrode, a drain electrode, and a source electrode. The transistor has a channel region between the drain electrode (drain electrode terminal, drain electrode region, or drain electrode) and the source electrode (source electrode terminal, source electrode region, or source electrode), and a current can flow through the drain electrode, the channel region, and the source electrode. In the specification, the channel region refers to a region through which a current mainly flows.

In the specification, a first electrode may be a drain electrode and a second electrode may be a source electrode, or, a first electrode may be a source electrode and a second electrode may be a drain electrode. In a case that transistors with opposite polarities are used, or in a case that a direction of a current is changed during operation of a circuit, or the like, functions of the “source electrode” and the “drain electrode” are sometimes interchangeable. Therefore, the “source electrode” and the “drain electrode” are interchangeable in the specification. In addition, the gate may also be referred to as a control electrode.

In the specification, “parallel” refers to a state in which an angle formed by two straight lines is −10° or more and 10° or less, and thus also includes a state in which the angle is −5° or more and 5° or less. In addition, “perpendicular” refers to a state in which an angle formed by two straight lines is 80° or more and 100° or less, and thus also includes a state in which the angle is 85° or more and 95° or less.

In this specification, a circle, oval, triangle, rectangle, trapezoid, pentagon or hexagon, etc. is not strictly speaking, but may be an approximate circle, oval, triangle, rectangle, trapezoid, pentagon or hexagon, etc. Some small deformations due to tolerances may exist, for example, guide angles, curved edges and deformations thereof may exist.

In the present disclosure, “about” and “substantially” refer to that a boundary is not defined strictly and a case within a range of process and measurement errors is allowed. In the present disclosure, “substantially the same” refers to a case where numerical values differ by less than 10%.

In the present disclosure, “A extends along a B direction” means that A may include a main body portion and a secondary portion connected with the main body portion, the main body portion is a line, a line segment, or a strip-shaped body, the main body portion extends along the B direction, and a length of the main body portion extending along the B direction is greater than a length of the secondary portion extending along another direction. “A extends in in the B direction” in the present disclosure means “the main body portion of A extends in the B direction”.

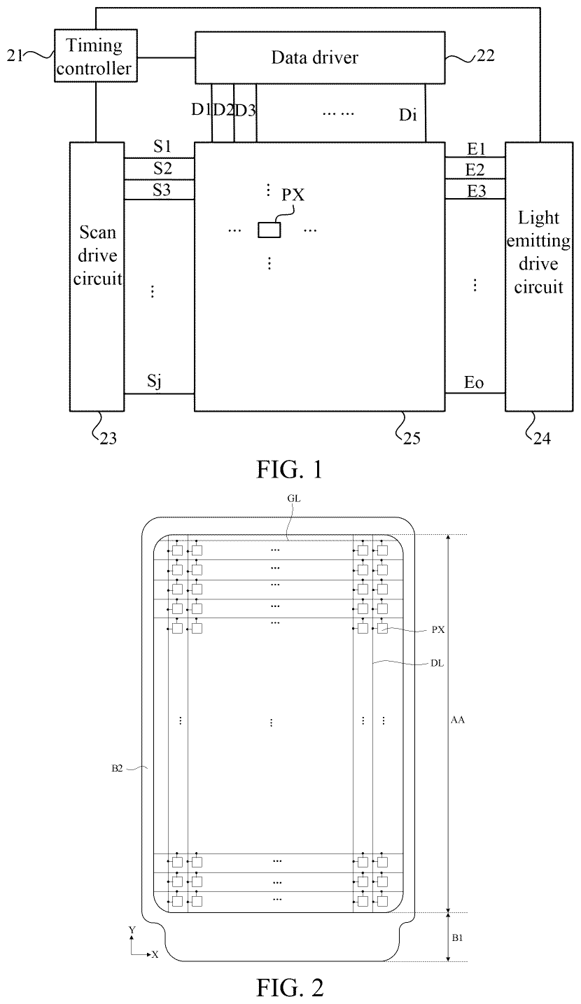

FIG. 1 is a schematic diagram of a structure of a display apparatus. In some examples, as shown in FIG. 1, the display apparatus may include a timing controller 21, a data driver 22, a scan drive circuit 23, a light emitting drive circuit 24, and a sub-pixel array 25. In some examples, the sub-pixel array 25 may include a plurality of sub-pixels PX arranged regularly. The scan drive circuit 23 may be configured to provide a scan signal to a sub-pixel PX along a scan line. The data driver 22 may be configured to provide a data voltage to a sub-pixel PX along a data line. The light emitting drive circuit 24 may be configured to provide a light emitting control signal to a sub-pixel PX along a light emitting control line. The timing controller 21 may be configured to control the scan drive circuit 23, the light emitting drive circuit 24 and the data driver 22.

In some examples, as shown in FIG. 1, the timing controller 21 may provide the data driver 22 with a gray-scale value and a control signal suitable for a specification of the data driver 22; the timing controller 21 may provide the scan driver circuit 23 with a scan clock signal, a scan start signal, etc., suitable for a specification of the scan drive circuit 23; and the timing controller 21 may provide the light emitting drive circuit 24 with a light emitting clock signal, a light emitting start signal, etc., suitable for a specification of the light emitting drive circuit 24. The data driver 22 may generate a data voltage to be provided to data lines D1 to Di, using the gray-scale value and the control signal received from the timing controller 21. For example, the data driver 22 may sample the gray-scale value using the clock signal and apply the data voltage corresponding to the gray-scale value to the data lines DI to Di using a sub-pixel row as a unit. The scan drive circuit 23 may receive the scan clock signal, the scan start signal, etc., from the timing controller 21 to generate a scan signal to be provided to scan lines S1 to Sj. For example, the scan drive circuit 23 may sequentially provide scan signals with on-level pulses to scan lines. In some examples, the scan driver 23 may include a shift register and sequentially transmit the scan start signal provided in a form of an on-level pulse to a next-stage circuit to generate the scan signal under the control of the scan clock signal. The light emitting drive circuit 24 may receive the light emitting clock signal, the light emitting start signal, etc., from the timing controller 21 to generate a light emitting control signal to be provided to light emitting control lines E1 to Eo. For example, the light emitting drive circuit 24 may provide sequentially light emitting control signals with an off-level pulse to light emitting control lines. The light emitting drive circuit 24 may include a shift register, and generate a light emitting control signal by sequentially transmitting a light emitting start signal provided in a form of an off-level pulse to a next-stage circuit under control of the clock signal. Herein, i, j, and o are all natural numbers.

In some examples, the display apparatus may include a display substrate. The sub-pixel array, the scan drive circuit and the light emitting drive circuit may be directly disposed on the display substrate. For example, the scan drive circuit may be dispose on the left bezel of the display substrate, and the light emitting drive circuit may be disposed on the right bezel of the display substrate; Alternatively, both the left bezel and right bezel of the display substrate may be provided with a scan drive circuit and a light-emitting drive circuit. In some examples, the scan drive circuit and the light emitting drive circuit may be formed together with the sub-pixels in a process of forming the sub-pixels.

In some examples, the data driver may be disposed on a separate chip or a printed circuit board. For example, the data driver may be formed and disposed on the lower bezel of the display substrate using a chip on glass, a chip on plastics, a chip on film, etc., to be connected to the drive chip pin. The timing controller may be disposed separately from or integrally with the data driver. However, the present embodiment is not limited thereto.

FIG. 2 is a schematic plan view of a display substrate. In some examples, as shown in FIG. 2, the display substrate may include a display region AA, a bonding region B1 located on one side of the display region AA, and a bezel region B2 located on another side of the display region AA. The bonding region B1 may be, for example, a lower bezel of the display substrate, and the bezel region B2 may include an upper bezel, a left bezel, and a right bezel of the display substrate. In some examples, the display region AA may be a flat area including a plurality of sub-pixels PX that form a pixel array, wherein the plurality of sub-pixels PX are configured to display a dynamic picture or a static image. The display region may be referred to as an effective region. In some examples, the display substrate may be a flexible substrate. Accordingly, the display substrate may be deformable, for example, crimped, bent, folded, or curled.

In some examples, the bezel region B2 may include a circuit region, a power supply line region, a crack dam region, and a cutting region which are sequentially disposed along a direction of the display region AA. The circuit region may be connected with the display region AA and may at least include multiple cascaded gate drive circuits electrically connected to a plurality of gate lines in the display region AA. The power supply line region is connected to the circuit region and may at least include a low-level power supply line. The low-level power supply line may extend along a direction parallel to an edge of the display region and is connected to a cathode in the display region. The crack dam region may be connected to the power supply line region and may at least include a plurality of cracks disposed on the composite insulation layer. The cutting region may be connected to the crack dam region, and may at least include a cutting groove disposed on the composite insulation layer. The cutting grooves are configured such that a cutting device may cut along the cutting grooves respectively after preparation of all film layers of the display substrate are completed.

In some examples, the bonding region B1 and the bezel region B2 may be provided with a first isolation dam and a second isolation dam, which may extend in a direction parallel to an edge of the display region to form a ring structure surrounding the display region AA, and the edge of the display region is an edge of a side of the display region close to the bonding region B1 or the bezel region B2.

In some examples, as shown in FIG. 2, the display region AA may at least include a plurality of sub-pixels PX, a plurality of gate lines GL, and a plurality of data lines DL. A plurality of gate lines GL may extend in a first direction X, and a plurality of data lines DL may extend in a second direction Y. Orthographic projections of the plurality of gate lines GL on the base substrate and orthographic projections of the plurality of data lines DL on the base substrate intersect to form a plurality of sub-pixel regions, and one sub-pixel PX is disposed in each sub-pixel region. The plurality of data lines DL are electrically connected with the plurality of sub-pixels PX, and the plurality of data lines DL may be configured to provide data signals to the plurality of sub-pixels PX. The plurality of data lines DL may extend to a bonding region B1. The plurality of gate lines GL are electrically connected with the plurality of sub-pixels PX, and the plurality of gate lines GL may be configured to provide gate control signals to the plurality of sub-pixels PX. In some examples, the gate control signal may include a scan signal and a light emitting control signal.

In some examples, as shown in FIG. 2, the first direction X may be an extension direction (row direction) of the gate lines GL in the display region AA, and the second direction Y may be an extension direction (column direction) of the data lines DL in the display region AA. The first direction X and the second direction Y may be perpendicular to each other.

In some examples, a pixel unit of the display region AA may include three sub-pixels which are a red sub-pixel, a green sub-pixel, and a blue sub-pixel respectively. However, the present embodiment is not limited thereto. In some examples, one pixel unit may include four sub-pixels, and the four sub-pixels are a red sub-pixel, a green sub-pixel, a blue sub-pixel, and a white sub-pixel respectively.

In some examples, a shape of a sub-pixel may be a rectangle, a rhombus, a pentagon, or a hexagon. When one pixel unit includes three sub-pixels, the three sub-pixels may be arranged in parallel in a horizontal direction, in parallel in a vertical direction, or in a manner like a Chinese character “ [symbol] ”; when one pixel unit includes four sub-pixels, the four sub-pixels may be arranged in parallel in a horizontal direction, in parallel in a vertical direction, or in a shape of a square. However, the present embodiment is not limited thereto.

In some examples, one sub-pixel may include a pixel circuit and a light emitting element electrically connected with the pixel circuit. The pixel circuit may include a plurality of transistors and at least one capacitor. For example, the pixel circuit may be of a 3T1C (i.e., three transistors and one capacitor) structure, a 7T1C (i.e., seven transistors and one capacitor) structure, a 5T1C (i.e., five transistors and one capacitor) structure, an 8T1C (eight transistors and one capacitor) structure, or an 8T2C (eight transistors and two capacitors) structure, or the like.

In some examples, the light emitting element may be any one of a Light Emitting Diode (LED), an Organic Light emitting Diode (OLED), a Quantum dot Light emitting Diode (QLED), a Micro LED (including a mini-LED or a micro-LED) and the like. For example, the light emitting element may be an OLED, and the light emitting element may emit red light, green light, blue light, or white light, etc. under driving of a pixel circuit corresponding to the light emitting element. A color of light emitted by the light emitting element may be determined as required. In some examples, the light emitting element may include an anode, a cathode, and an organic light emitting layer located between the anode and the cathode. The anode of the light emitting element may be electrically connected to a corresponding pixel circuit. However, the present embodiment is not limited thereto.

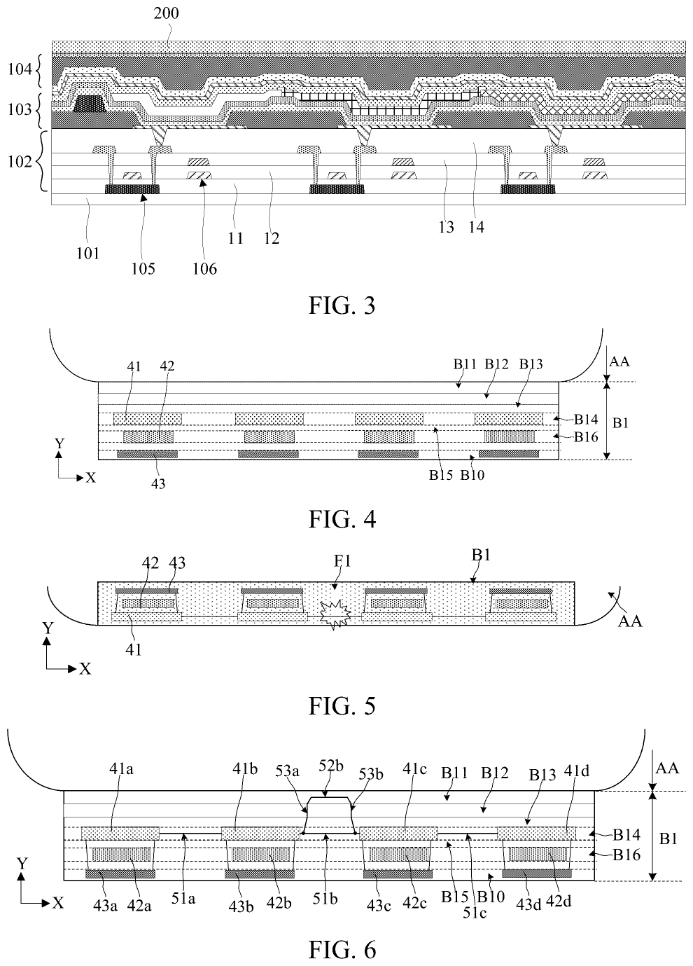

FIG. 3 is a schematic diagram of a partial sectional structure of a display region of a display substrate. FIG. 3 illustrates structures of three sub-pixels of the display substrate. In some example, as shown in FIG. 3, in a direction perpendicular to the display substrate, the display substrate may include: a base substrate 101, and a circuit structure layer 102, a light emitting structure layer 103, an encapsulation layer 104 and an encapsulation cover plate 200 that are sequentially disposed on the base substrate 101. In some possible implementations, the display substrate may include other film layers, such as a post spacer, a touch structure layer etc., which is not limited in the present disclosure herein.

In some examples, the base substrate 101 may be a rigid underlay substrate, e.g., a glass underlay substrate. However, the present embodiment is not limited thereto. For example, the base substrate may be a flexible underlay substrate, e.g., prepared from an insulation material like a resin. In addition, the base substrate may be a single-layer structure or a multilayer structure. When the base substrate is a multilayer structure, an inorganic material such as silicon nitride, silicon oxide, and silicon oxynitride may be arranged between a plurality of layers as a single layer or multiple layers.

In some examples, the circuit structure layer 102 of each sub-pixel may include a plurality of transistors and a storage capacitor which form a pixel circuit. Illustration is made in FIG. 3 by taking each sub-pixel including one transistor and one storage capacitor as an example. In some possible implementations, the circuit structure layer 102 of each sub-pixel may include: an active layer disposed on the base substrate 101; a first insulation layer 11 (or referred to as a first gate insulation layer) covering the active layer; a first gate metal layer (including, for example, a gate electrode of a transistor and a first capacitor electrode) disposed on the first insulation layer 11; a second insulation layer 12 (or referred to as a second gate insulation layer) covering the first gate metal layer; a second gate metal layer (e.g. including a second capacitor electrode) disposed on the second insulation layer 12; a third insulation layer 13 (or referred to as an interlayer insulation layer) covering the second gate metal layer, wherein the first insulation layer 11, the second insulation layer 12 and the third insulation layer 13 are provided with a plurality of first vias, and the plurality of first vias may expose the active layer; a first source-drain metal layer (including, for example, a source electrode and a drain electrode of a transistor) disposed on the third insulation layer 13, wherein the source electrode and the drain electrode may be connected to the active layer through first vias, respectively; and a first planarization layer 14 covering the structure, wherein the first planarization layer 14 is provided with a second via, the second via may expose the drain electrode. The active layer, the gate electrode, the source electrode, and the drain electrode may form the transistor 105, and the first capacitance electrode and the second capacitance electrode may form the storage capacitor 106.

In some examples, as shown in FIG. 3, the light emitting structure layer 103 may include an anode layer, a pixel definition layer, an organic light emitting layer, and a cathode. The anode layer may include an anode of a light-emitting element, the anode may be disposed on the first planarization layer 14, and electrically connected to the drain electrode of the transistor of the pixel circuit through a second via provided on the first planarization layer 14. The pixel definition layer is disposed on the anode layer and the first planarization layer, and a pixel opening is provided on the pixel definition layer, and the pixel opening exposes at least part of the surface of the anode. The organic light emitting layer is at least partially disposed in the pixel opening and is connected with the anode. The cathode is disposed on the organic light emitting layer, and is connected with the organic light emitting layer. The organic light emitting layer emits light of corresponding colors driven by the anode and the cathode.

In some examples, as shown in FIG. 3, the encapsulation structure layer 104 may include a first encapsulation layer, a second encapsulation layer, and a third encapsulation layer that are stacked. The first encapsulation layer and the third encapsulation layer may be made of an inorganic material, and the second encapsulation layer may be made of an organic material. The second encapsulation layer is arranged between the first encapsulation layer and the third encapsulation layer, which can ensure that outside water vapor cannot enter the light-emitting structure layer 103.

In some examples, the organic light emitting layer may at least include a hole injection layer, a hole transport layer, a light emitting layer and a hole block layer which are stacked on the anode. In some examples, the hole injection layers of all sub-pixels may be a common layer connected together; the hole transport layers of all sub-pixels may be a common layer connected together; the light emitting layers of adjacent sub-pixels may be slightly overlapped or isolated; and the hole block layers may be a common layer connected together. However, the present embodiment is not limited thereto.

FIG. 4 is a schematic diagram of a bonding region of a display substrate. FIG. 4 illustrates a schematic diagram of a display substrate before the bending process is performed. In some examples, as shown in FIG. 4, the bonding region B1 of the display substrate may include a first fan-out region B11, a bending region B12, a second fan-out region B13, a first circuit region B14, a third fan-out region B15, a drive chip region B16, and a bonding pin region B10 that are sequentially disposed along a direction away from the display region AA. The first fan-out region B11 may be connected to the display region AA. The first fan-out region B11 may at least include a first power supply line, a second power supply line, and a plurality of data lines, and the plurality of data lines may be configured to extend in a form of fan-out traces from data lines of the display region AA. The first power supply line of the first fan-out region B11 may be configured to connect to a high-level power supply line of the display region, and the second power supply line may be configured to connect to a low-level power supply line of the bezel region. The bending region B12 is connected between the first fan-out region B11 and the second fan-out region B13, and may be configured such that the bonding region B1 is bent to the back of the display region AA. The first circuit region B14 may at least include a plurality of first circuit groups 41. The plurality of first circuit groups 41 may be arranged side by side along the first direction X. Each first circuit group 41 may include a plurality of test circuits, which may be configured to be electrically connected to a plurality of data lines of the display region AA to provide test data signals to the plurality of data lines of the display region AA during a test phase. The drive chip region B16 may include a plurality of drive chip pin groups 42. The plurality of drive chip pin groups 42 may be electrically connected to a plurality of data lines and be configured to be bonded to at least one drive chip (IC, Integrated Circuit). For example, each drive chip pin group 42 may be configured to be bonded to one drive chip. The drive chip may be configured to generate a drive signal required for driving sub-pixels and to provide the drive signal to the data lines of the display region. For example, the drive signal may be a data signal that drives the sub-pixels. The bonding pin region B10 may include a plurality of bonding pin groups 43, and each bonding pin group 43 may include a plurality of bonding pins sequentially arranged along the first direction X. Each bonding pin group 43 may be configured to be bonded and connected to corresponding at least one circuit board (e.g., FPC (Flexible Printed Circuit)).

FIG. 5 is a schematic diagram of a display substrate after the bending process is performed. In some examples, as shown in FIG. 5, after the display substrate has undergone the bending process, a region on a side of the bending region away from the display region AA (e.g., the region including the first circuit region, the third fan-out region, the drive chip region, and the bonding pin region) may be bent to the back of the display region AA. In this way, orthographic projections of the first circuit group 41, the drive chip pin group 42, and the bonding pin group 43 on the base substrate may overlap with the display region AA. The shadow portion of the bonding region B1 in FIG. 5 shows a region where the Foam is located. In the bending process of the display substrate, the display substrate can be supported by foam attaching on the back of the display substrate, thereby improving the bending durability of the display substrate. After research, the inventor of the present application has found that in the bending process of the display substrate with a narrow bezel and a medium or large size, a multi-segment design of foam is used, and there is a gap F1 between each segment of foam. A length of the gap F1 along the first direction X is about 1 millimeter (mm). After the display substrate is bent, the bonding region of the display substrate lacks support at the position corresponding to the gap F1 between the foams, so that the traces of the bonding region corresponding to the position of the gap F1 have a risk of line breakage, which affects the yield of the display substrate.

This embodiment provides a display substrate which includes a base substrate, a plurality of first circuit groups, at least one group of first connection lines, and at least one group of second connection lines. The base substrate includes a display region, and a bonding region on a side of the display region. The plurality of first circuit groups, the at least one group of first connection lines, and the at least one group of second connection lines are located in the bonding region. The plurality of first circuit groups are arranged along a first direction. At least two adjacent first circuit groups of the plurality of first circuit groups are electrically connected by a group of first connection lines and a group of second connection lines. A first connection line and a second connection lines in the group of first connection lines and the group of second connection lines, transmitting a same signal, are connected in parallel, and at least one group of second connection lines is located on a side of at least one group of first connection lines close to the display region.

The display substrate provided by the present embodiment can provide double insurance for signal transmission between adjacent first circuit groups by disposing a first connection line and a second connection line that are connected in parallel in the adjacent first circuit groups. By ensuring that at least one of the first connection line and the second connection line is turned on, the yield loss of the display substrate caused by the line breakage of the bonding region in the bending process can be avoided effectively.

In the present embodiment, the parallel connection of A and B may represent a connection mode in which the heads of A and B are connected, and the tails of A and B are also connected.

In some exemplary implementations, two adjacent first circuit groups of the plurality of first circuit groups are electrically connected by a group of first connection lines and a group of second connection lines. In this example, two first circuit groups may be connected by a first connection line and a second connection line, and remaining adjacent first circuit groups may be connected only by first connection lines. This example may be applicable to the case where two segments of foams are used (i.e. there is only one foam gap).

In some exemplary implementations, any two adjacent first circuit groups of the plurality of first circuit groups may be electrically connected by a group of first connection lines and a group of second connection lines. In this example, all adjacent first circuit groups are connected by first connection lines and second connection lines. This example may be applicable to the case where multiple segments of foams are used (e.g., there are multiple foam gaps).

In some exemplary implementations, the bonding region may include a first sub-region, a bending region, and a second sub-region sequentially disposed along a direction away from the display region. The plurality of first circuit groups and the at least one group of first connection lines may be located in the second sub-region, and the at least one group of second connection lines may be located in the first sub-region. For example, the first sub-region may include a first fan-out region; the second sub-region may include: a second fan-out region, a first circuit region, a third fan-out region, a drive chip region, and a bonding pin region. However, the present embodiment is not limited thereto. In this example, by disposing the second connection lines in the first sub-region, the second connection lines would not be bent to the back of the display region in the bending process, and the second connection lines may attach to the cover plate, so as to avoid being affected by the foam gap and ensure the signal transmission of the second connection lines.

In some exemplary implementations, the display region includes a plurality of sub-pixels and a plurality of data lines, wherein the plurality of data lines are electrically connected to the plurality of sub-pixels. At least one first circuit group of the plurality of first circuit groups may include a plurality of test circuits, the plurality of test circuits may be electrically connected to a plurality of data lines, and be configured to provide test data signals to the plurality of data lines during a test phase.

Solutions of the present embodiment will be described below through some examples.

FIG. 6 is a schematic diagram of a bonding region of a display substrate according to at least one embodiment of the present disclosure. In some examples, as shown in FIG. 6, the bonding region B1 of the display substrate may include a first fan-out region B11, a bending region B12, a second fan-out region B13, a first circuit region B14, a third fan-out region B15, a drive chip region B16, and a bonding pin region B10, that are sequentially disposed along a direction away from the display region AA. The first circuit region B14 may include a plurality of first circuit groups (e.g., including four first circuit groups 41a, 41b, 41c, and 41d). The four first circuit groups 41a, 41b, 41c, and 41d may be arranged sequentially along the first direction X. The drive chip region B16 may include a plurality of drive chip pin groups (e.g., including four drive chip pin groups 42a, 42b, 42c, and 42d). The four drive chip pin groups 42a, 42b, 42c, and 42d may be arranged sequentially along the first direction X. The bonding pin region B10 may include a plurality of bonding pin groups (e.g., including four bonding pin groups 43a, 43b, 43c, and 43d). The four bonding pin groups 43a, 43b, 43c, and 43d may be arranged sequentially along the first direction X. In this example, the numbers of the first circuit groups, the drive chip pin groups and the bonding pin groups may be the same. A first circuit group corresponds to a drive chip pin group, a first circuit group corresponds to a bonding pin group, and a drive chip pin group corresponds to a bonding pin group. For example, the first circuit group 41a, the drive chip pin group 42a, and the bonding pin group 43a correspond to each other, the first circuit group 41b, the drive chip pin group 42b, and the bonding pin group 43b correspond to each other, the first circuit group 41c, the drive chip pin group 42c, and the bonding pin group 43c correspond to each other, and the first circuit group 41d, the drive chip pin group 42d, and the bonding pin group 43d correspond to each other.

In some examples, as shown in FIG. 6, adjacent first circuit groups may be electrically connected by a first connection line, thereby ensuring the consistency of signal transmission and further ensuring the uniformity of the display region. For example, the first circuit groups 41a and 41b may be electrically connected by a first connection line 51a, the first circuit groups 41b and 41c may be electrically connected by a first connection line 51b, and the first circuit groups 41c and 41d may be electrically connected by a first connection line 51c. The first circuit groups 41b and 41c may also be electrically connected by a second connection line 52b. The example may be applicable to the case shown in FIG. 5, i.e., the case where trace breakage caused by the foam gap F1 is alleviated by disposing the second connection line 52b. In some examples, as shown in FIGS. 5 and 6, a buffer layer (e.g., foam) may be provided on the back of the base substrate, and orthographic projections of the second connection line 52b and the first connection line 51b on the display substrate may partially overlap with the buffer layer. The orthographic projection of the first connection line 51b on the base substrate is not completely covered by the buffer layer. And since the foam gap F1 in the buffer layer will cause the line breakage, by disposing the second connection line 52b in the first fan-out region B11, the second connection line 52b does not need to be bent to the back of the display region, and does not need to be supported by the buffer layer, the stability of signal transmission can be ensured, thereby improving the yield of the display substrate.

In some examples, as shown in FIG. 6, the second connection line 52b and the first connection line 51b may be connected in parallel. The second connection line 52b may be located in the first fan-out region B11, the first connection line 51b may be located on a side of the bending region B12 away from the display region AA, and the first connection line 51b may be located between the first circuit groups 41b and 41c in the first direction X. One end of the second connection line 52b may be electrically connected to one end of the first connection line 51b through a bending connection line 53a, and the other end of the second connection line 52b may be electrically connected to the other end of the first connection line 51b through another bending connection line 53b, thus enabling the parallel connection of the first connection line 51b and the second connection line 52b transmitting the same signal.

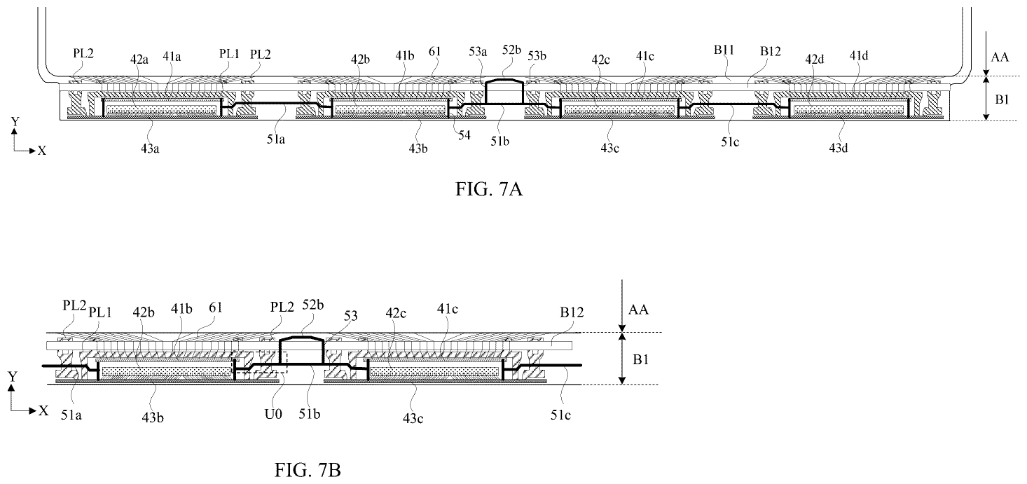

FIG. 7A is an example diagram of a bonding region of a display substrate according to at least one embodiment of the present disclosure. FIG. 7B is a partial schematic diagram of the bonding region in FIG. 7A. In some examples, as shown in FIGS. 7A and 7B, the first fan-out region B11 further includes a plurality groups of first fan-out traces 61. The plurality groups of first fan-out traces 61 may be arranged along the first direction X. Each group of first fan-out traces 61 may include a plurality of first fan-out traces, and the first fan-out traces may include data extension lines of a plurality of data lines of a display region in a bonding region. The plurality of first fan-out traces in each group of first fan-out traces 61 extend towards an middle position of a corresponding first circuit group. The second connection line 52b may be located between two adjacent groups of first fan-out traces, for example, between two groups of first fan-out traces electrically connected by the first circuit groups 41b and 41c. The orthographic projection of the second connection line 52b on the base substrate does not overlap with the orthographic projections of adjacent two groups of first fan-out traces on the base substrate.

In some examples, as shown in FIGS. 7A and 7B, the bonding region B1 may include a plurality of first power supply lines PL1 and a plurality of second power supply lines PL2. A bonding pin group (e.g., the bonding pin group 43b) within the bonding pin region B10 may be electrically connected to two second power supply lines PL2 and one first power supply line PL1, the first power supply line PL1 may be located between the two second power supply lines PL2 in the first direction X. For example, the first power supply line PL1 may be electrically connected to a first power supply pin of the bonding pin group within the bonding pin region B10, and the second power supply line PL2 may be electrically connected to a second power supply pin of the bonding pin group. In some examples, the first power supply line PL1 and the second power supply line PL2 may be a single-layer trace, for example, may be located in the first source-drain metal layer or the second source-drain metal layer. Alternatively, the first power supply line PL1 and the second power supply line PL2 may be a double-layer trace, for example, may be traces in a stacked structure of the first source-drain metal layer and the second source-drain metal layer. The present embodiment is not limited thereto.

In some examples, as shown in FIGS. 7A and 7B, pins of the drive chip pin group may be electrically connected to pins of a corresponding bonding pin group through pin connection lines. The pin connection lines may extend substantially in the second direction Y, and may be arranged sequentially along the first direction X. The present embodiment is not limited thereto.

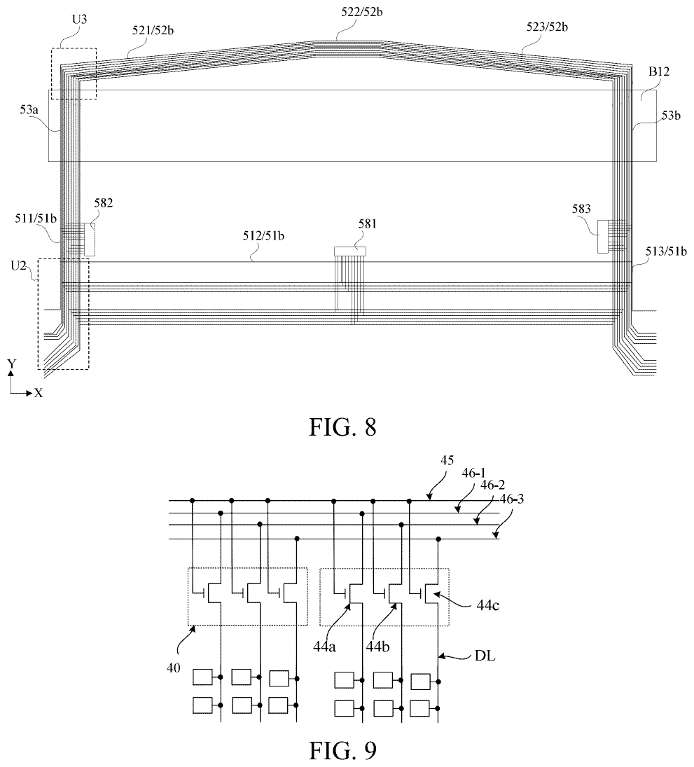

FIGS. 6 to 7B illustrate the first connection line and the second connection line by taking one signal transmission between adjacent first circuit groups as an example. FIG. 8 is a partial schematic diagram of a bonding region according to at least one embodiment of the present disclosure. FIG. 8 illustrates a group of first connection lines and a group of second connection lines between adjacent first circuit groups. A group of first connection lines may include a plurality of first connection lines 51b extending in substantially the same direction, and a group of second connection lines may include a plurality of second connection lines 52b extending in substantially the same direction. FIG. 8 is illustrated by taking reference signs of a first connection line and a second connection line as an example.

In some examples, as shown in FIG. 8, a first connection line 51b may include a first trace segment 511, a second trace segment 512 and a third trace segment 513 that are electrically connected sequentially. The second trace segment 512 may extend in the first direction X, and two ends of the second trace segment 512 may be electrically connected to the first trace segment 511 and the third trace segment 513, respectively. For example, the second trace segment 512 may be electrically connected to the first trace segment 511 through a first jumping line, and may be electrically connected to the third trace segment 513 through a second jumping line. The first trace segment 511 may include a first extension segment and a second extension segment electrically connected to each other; the first extension segment may extend in the second direction Y and be electrically connected to the second connection line 52b through a bending adapter line 53a; the second extension segment may extend at least in the first direction X and be electrically connected to a first circuit group. The third trace segment 513 may include a third extension segment and a fourth extension segment electrically connected to each other; the third extension segment may extend in the second direction Y and be electrically connected to the second connection line 52b through a bending adapter line 53b; the fourth extension segment may extend at least in the first direction X and be electrically connected to another first circuit group. In some examples, the first trace segment 511, the second trace segment 512, and the third trace segment 513 of the first connection line 51b may be of the same layer structure, e.g., located in the first gate metal layer or the second gate metal layer. The first jumping line and the second jumping line may be of the same layer structure, e.g., located in the first source-drain metal layer.

In some examples, as shown in FIG. 8, a second connection line 52b may include a fourth trace segment 521, a fifth trace segment 522, and a sixth trace segment 523 that are electrically and sequentially connected. The fifth line segment 522 may extend in the first direction X, and be located on a side of the fourth trace segment 521 and the sixth trace segment 523 close to the display region. The fourth trace segment 521 and the sixth trace segment 523 are located on a side of the fifth trace segment 522 close to the bending region B12. The fourth trace segment 521 may extend in substantially the same direction as an adjacent first fan-out trace, and the sixth trace segment 523 may extend in substantially the same direction as an adjacent first fan-out trace. The fourth and sixth trace segments 521 and 523 may be substantially symmetrical with respect to a midline of the fifth trace segment 522 in the first direction X. One end of the fourth trace segment 521 may be electrically connected to the bending connection line 53a, and the other end may be electrically connected to one end of the fifth trace segment 522. One end of the sixth trace segment 523 may be electrically connected to the bending connection line 53b, and the other end may be electrically connected to the other end of the fifth trace segment 522. In some examples, the length of the fifth trace segment 522 of the second connection line 52b along the first direction X may be less than the shortest distance between the first trace segment 511 and the third trace segment 513 of the first connection line 51b to which the second connection line 52b is electrically connected. In some examples, a fourth trace segment 521, a fifth trace segment 522, and a sixth trace segment 523 of a second connection line 52b may be of an integral structure, for example, located in the first gate metal layer or the second gate metal layer. However, the present embodiment is not limited thereto.

In some examples, as shown in FIG. 8, the bonding region may also include a plurality of first electrostatic discharge circuit groups (e.g., first electrostatic discharge circuit groups 581, 582, and 583). The first electrostatic discharge circuit groups 581, 582, and 583 may be located on a side of the bending region B12 away from the display region. Each first electrostatic discharge circuit group may include a plurality of first electrostatic discharge circuits. For example, a plurality of first electrostatic discharge circuits in the first electrostatic discharge circuit group 581 may be electrically connected to the second trace segments 512 of the plurality of first connection lines 51b, respectively, and be configured to release the electrostatic of the second trace segments 512, and a first electrostatic discharge circuit electrically connected to a second trace segment 512 may be located on a side of the second trace segment 512 close to the bending region B12. A plurality of first electrostatic discharge circuits in the first electrostatic discharge circuit group 582 may be electrically connected to the first trace segments 511 of the plurality of first connection lines 51b, respectively, and a first electrostatic discharge circuit electrically connected to a first trace segment 511 may be located on a side of the first trace segment 511 close to the third trace segment 513. A plurality of first electrostatic discharge circuits in the first electrostatic discharge circuit group 583 may be electrically connected to the third trace segments 513 of the plurality of first connection lines 51b, respectively, and a first electrostatic discharge circuit electrically connected to a third trace segment 513 may be located on a side of the third trace segment 513 close to the first trace segment 511. The position arrangement of the first electrostatic discharge circuits in the present example can avoid affecting the arrangement of the first connection lines, and is beneficial to improving the space utilization rate. In the present example, the number and position arrangement of the first electrostatic discharge circuits are not limited. In the present example, a plurality of first electrostatic discharge circuit groups are provided to facilitate the release of electrostatic of the first connection lines and the second connection line, thereby avoiding electrostatic interference.

FIG. 9 is an equivalent circuit diagram of a test circuit according to at least one embodiment of the present disclosure. In some examples, the first circuit group of the bonding region may include a plurality of test circuits 40. The test circuit 40 may include a plurality of test transistors (including, for example, a first test transistor 44a, a second test transistor 44b, and a third test transistor 44c). As shown in FIG. 9, a gate of the first test transistor 44a, a gate of the second test transistor 44b, and a gate of the third test transistor 44c are all connected to the same test control signal line 45. A first electrode of the first test transistor 44a is connected to a first test data line 46-1, a first electrode of the second test transistor 44b is connected to a second test data line 46-2, and a first electrode of the third test transistor 44c is connected to a third test data line 46-3. The second electrodes of the first test transistor 44a, the second test transistor 44b, and the third test transistor 44c are connected to different data lines DL in the display region, respectively. That is, the second electrode of the first test transistor 44a is connected to a data line DL, the second electrode of the second test transistor 44b is connected to another data line DL, and the second electrode of the third test transistor 44c is connected to still another data line DL. In this way, through the test control signal line 45, the turn-on of three test transistors in the test circuit 40 may be controlled, and signals of different test data lines may be controlled to be written into different data lines DL. During the test, by providing a turned-on signal to the test control signal line 45 and providing the required test data signals to a plurality of test data lines respectively, the plurality of data lines in the display region are enabled to obtain the test data signals to achieve test.

In some examples, a color of a sub-pixel connected with each data line may be the same. During the test, same test data signals are provided to the data lines corresponding to the sub-pixels of the same color, so that these sub-pixels may be displayed in the same way, thereby whether there is a defective sub-pixel through the color of the display image is determined, and the defective sub-pixel is located.

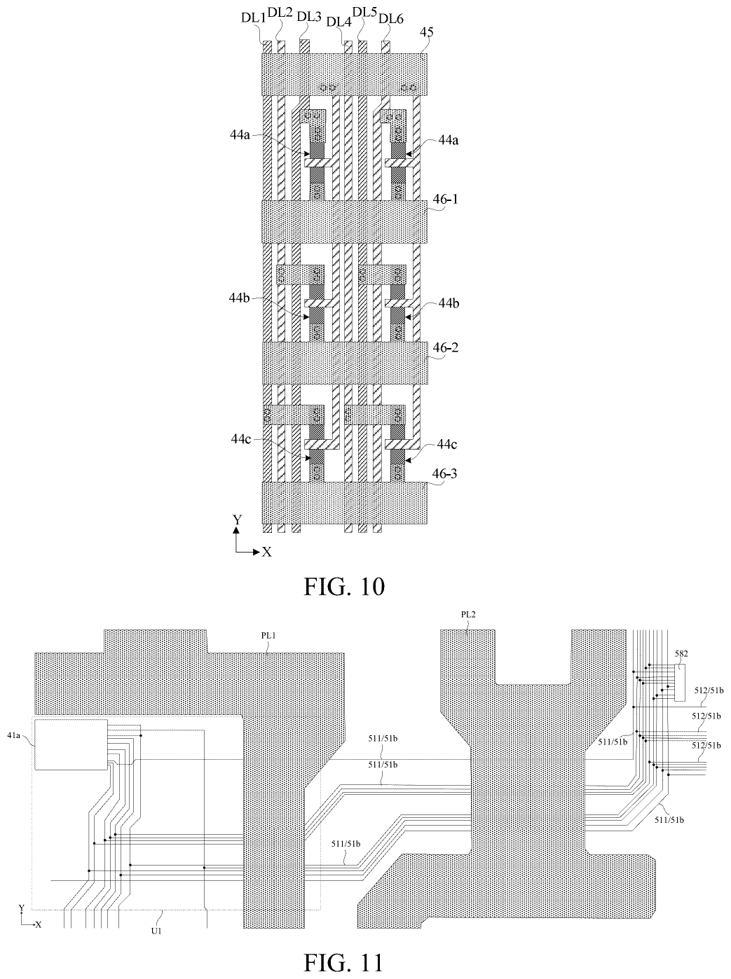

FIG. 10 is a schematic plan view of a test circuit according to at least one embodiment of the present disclosure. FIG. 10 illustrates two test circuits arranged along the first direction X. In some examples, as shown in FIG. 10, the first test transistor 44a, the second test transistor 44b, and the third test transistor 44c of the test circuit may be arranged sequentially along the second direction Y. The test control signal line 45, the first test data line 46-1, the second test data line 46-2, and the third test data line 46-3 may be arranged sequentially along the second direction Y, and extend at least in the first direction X. The test control signal line 45, the first test data line 46-1, the second test data line 46-2, and the third test data line 46-3 may be located on the first source-drain metal layer. Active layers of the three test transistors of the test circuit and active layers of the transistors of the pixel circuit of the sub-pixel may be of the same layer structure. The gate of the first test transistor 44a, the gate of the second test transistor 44b, and the gate of the third test transistor 44c of a test circuit may be of an integral structure and be located on the first gate metal layer, and further, may be electrically connected to the test control signal line 45 located on the first source-drain metal layer. A first electrode of a first test transistor 44a may be electrically connected to a first test data line 46-1 located on the first source-drain metal layer, and a second electrode of the first test transistor 44a may be electrically connected to a data line DL3 located on the second gate metal layer through a connection electrode located on the first source-drain metal layer. A first electrode of a second test transistor 44b may be electrically connected to a second test data line 46-2 located on the first source-drain metal layer, and a second electrode of the second test transistor 44b may be electrically connected to a data line DL2 located on the first gate metal layer through a connection electrode located on the first source-drain metal layer. A first electrode of a third test transistor 44c may be electrically connected to a third test data line 46-3 located on the first source-drain metal layer, and a second electrode of the third test transistor 44c may be electrically connected to a data line DLI located on the second gate metal layer through a connection electrode located on the first source-drain metal layer. The three test transistors of another test circuit may be electrically connected to the data lines DL4, DL5 and DL6, respectively.

In some examples, the test control signal line 45 and the three test data lines (e.g., the first test data line 46-1, the second test data line 46-2 and the third test data line 46-3) electrically connected to the test circuits in the first circuit group may each be electrically connected to the test circuits in an adjacent first circuit group through a first connection line (or a first connection line and a second connection line).

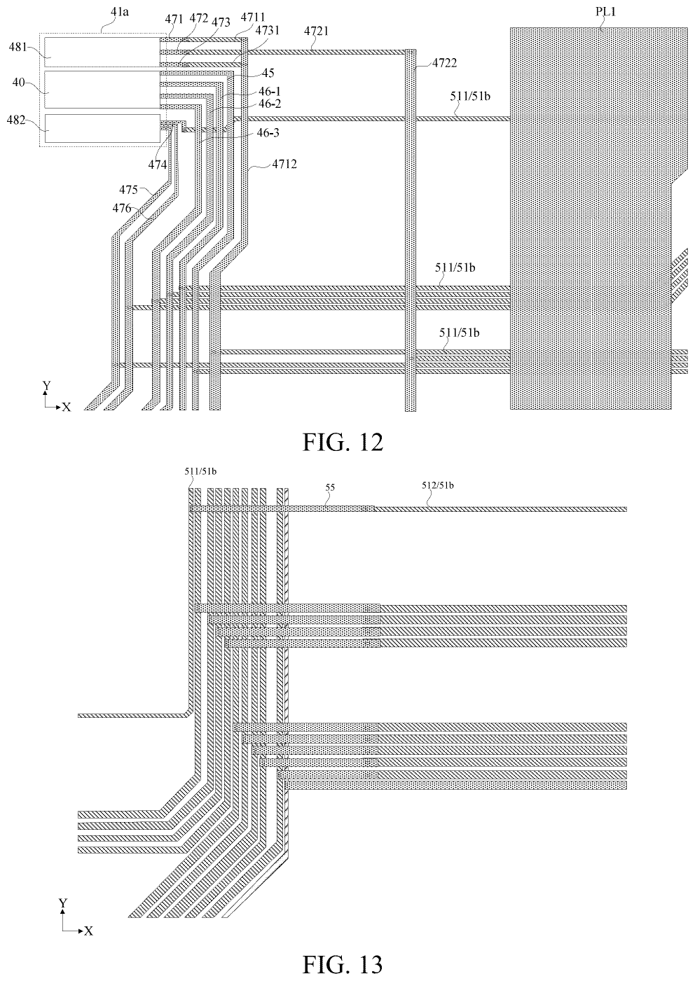

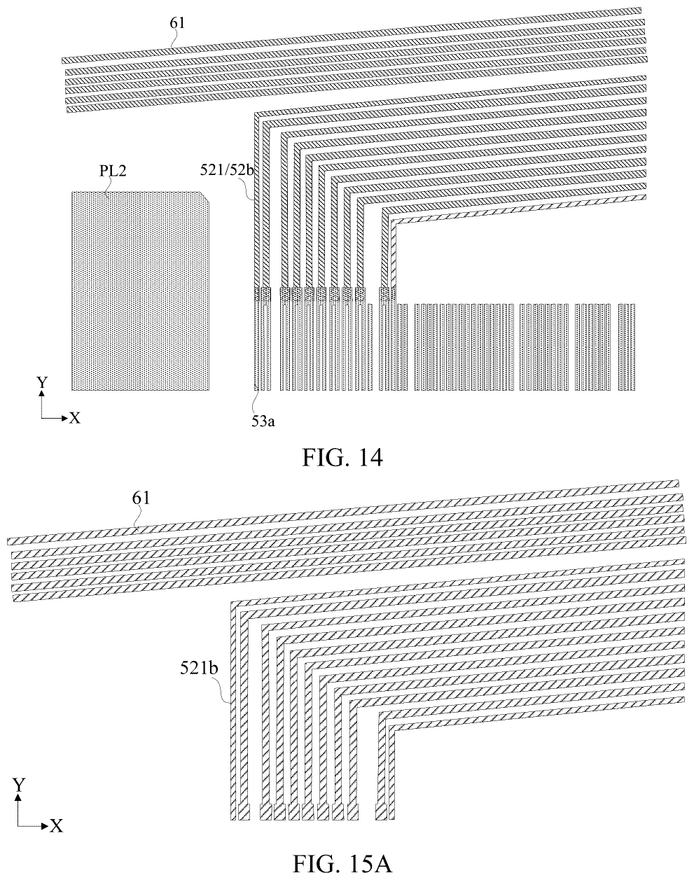

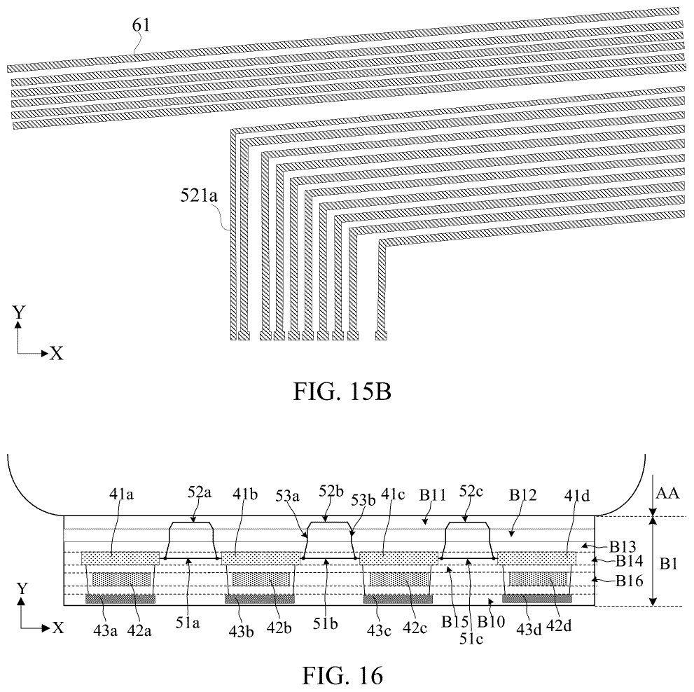

FIG. 11 is a partial schematic diagram of a connection position between a first circuit group and a group of first connection lines according to at least one embodiment of the present disclosure. FIG. 11 is a partial enlarged view of a region U0 in FIG. 7B. FIG. 12 is a partial enlarged view of a region U1 in FIG. 11. FIG. 13 is a schematic diagram of a connection position of a first trace segment and a second trace segment of a first connection line according to at least one embodiment of the present disclosure, and FIG. 13 is a partial enlarged view of a region U2 in FIG. 8. FIG. 14 is a schematic diagram of a connection position of a fourth trace segment of a second connection line and a bending connection line according to at least one embodiment of the present disclosure, and FIG. 14 is a partial enlarged view of a region U3 in FIG. 8. FIG. 15A is a schematic diagram of a first gate metal layer in FIG. 14. FIG. 15B is a schematic diagram of a second gate metal layer in FIG. 14. FIGS. 11 to 15B illustrate a connection structure among a first circuit group, a first trace segment of a first connection line, and a fourth trace segment of a second connection line. The connection structure among the sixth trace segment of the second connection line, the third trace segment of the first connection line, and another first circuit group is similar to the connection structure among the fourth trace segment of the second connection line, the first trace segment of the first connection line, and the one first circuit group, so it will not be described here repeatedly. FIGS. 11 to 15B illustrate examples by signed first connection line and second connection line, or signed three first connection lines.

In some examples, as shown in FIGS. 11 and 12, the first circuit group 41a may include a plurality of test circuits 40, a plurality of second electrostatic discharge circuits 481, and a plurality of detection circuits 482. The plurality of second electrostatic discharge circuits 481 may be arranged sequentially along the first direction X, and the plurality of test circuits 40 may be arranged along the first direction X. The plurality of detection circuits 482 may be sequentially arranged along the first direction X. In the second direction Y, the plurality of test circuits 40 may be located on a side of the plurality of second electrostatic discharge circuits 481 away from the display region, and the plurality of detection circuits 482 may be located on a side of the plurality of test circuits 40 away from the display region. The detection circuits 482 may be configured to provide signals required for picture detection to a plurality of data lines.

In some examples, as shown in FIGS. 11 and 12, the test control signal line 45, the first test data line 46-1, the second test data line 46-2, and the third test data line 46-3 electrically connected to the plurality of test circuits 40 may each be electrically connected to a first trace segment 511 of a corresponding first connection line 51b. The test control signal line 45, the first test data line 46-1, the second test data line 46-2, and the third test data line 46-3 may extend substantially in the second direction Y to the bonding pin region and be electrically connected to corresponding bonding pins in the bonding pin region.

In some examples, as shown in FIGS. 11 and 12, the plurality of second electrostatic discharge circuits 481 may be electrically connected to a first voltage line 471, a second voltage line 472, and a third voltage line 473. For example, the first voltage line 471 and the third voltage line 473 may be electrically connected and configured to transmit a high-potential voltage, and the second voltage line 472 may be configured to transmit a low-potential voltage. The second voltage line 472 may be located between the first voltage line 471 and the third voltage line 473 in the second direction Y. The first voltage line 471, the second voltage line 472, and the third voltage line 473 may all be located on the first source-drain metal layer. For example, the first voltage line 471 and the third voltage line 473 may be electrically connected to the second conductive line 4712 located on the first source-drain metal layer through first conductive lines 4711 and 4731 located on the first gate metal layer, respectively, and be electrically connected to a corresponding first connection line 51b through the second conductive line 4712, for example, the second conductive line 4712 may be electrically connected to a first trace segment 511 of a first connection line 51b located on the second gate metal layer. The second voltage line 472 may be electrically connected to a fourth conductive line 4722 (which is located on the first source-drain metal layer and extends in the second direction Y) through a third conductive line 4721 located on the first gate metal layer, and be electrically connected to a corresponding first connection line 51b through the fourth conductive line 4722, for example, the fourth conductive line 4722 may be electrically connected to a first trace segment 511 of a corresponding first connection line 51b located on the second gate metal layer. The second conductive line 4712 located on the first source-drain metal layer and electrically connected to the first voltage line 471 and the third voltage line 473, and the fourth conductive line 4722 located on the first source-drain metal layer and electrically connected to the second voltage line 472, may extend substantially in the second direction Y to the bonding pin region and be electrically connected to corresponding bonding pins in the bonding pin region.

In some examples, as shown in FIGS. 11 and 12, a plurality of detection circuits 482 may be electrically connected to a plurality of panel detection lines (including, for example, a first panel detection line 474, a second panel detection line 475, and a third panel detection line 476). The plurality of panel detection lines may be configured to transmit signals required by the detection circuits. The first panel detection line 474, the second panel detection line 475, and the third panel detection line 476 may be located on the first source-drain metal layer and each be electrically connected to a first trace segment 511 of a corresponding first connection line 51b. The first panel detection line 474, the second panel detection line 475, and the third panel detection line 476 may extend in the second direction Y to the bonding pin region and be electrically connected to corresponding bonding pins in the bonding pin region.

In some examples, as shown in FIGS. 11 and 12, after electrically connected to the signal lines of the first circuit group 41a, first trace segments 511 of the plurality of first connection lines 51b may extend substantially in the first direction X passing a region where a first power supply line PL1 and a second power supply line PL2 are located, and then extend in the second direction Y towards the bending region. An extension part of a first trace segment 511 in the second direction Y may be electrically connected to a corresponding second trace segment 512.

In some examples, as shown in FIG. 13, the first trace segments 511 of a plurality of first connection lines 51b of a group of first connection lines may each be electrically connected to a second trace segment 512 through a first jumping line 55. The plurality of second trace segments 512 may be sequentially arranged along the second direction Y, and all extend in the first direction X.

In some examples, as shown in FIGS. 14 to 15B, a fourth trace segment 521 of a second connection line 52b may be electrically connected to a bending connection line 53a. The bending connection line 53a may be located on the first source-drain metal layer. The second connection line 52b may be a double-layer trace. For example, the fourth trace segment 521 of the second connection line 52b may include a first sub-trace 521a and a second sub-trace 521b that are stacked. The second sub-trace 521b may be located on the first gate metal layer, and the first sub-trace 521a may be located on the second gate metal layer. The second connection line of the present example adopts a double-layer trace, which can reduce the trace resistance. The first fan-out trace 61 may adopt a double-layer trace, which may include, for example, sub-traces located on the first gate metal layer and at the second gate metal layer. The present embodiment is not limited thereto.

In some examples, as shown in FIGS. 14 to 15B, orthographic projections of a fourth trace segment 521 of a second connection line 52b and an adjacent first fan-out trace 61 on the base substrate may not overlap. The extension direction of the fourth trace segment 521 may consistent with that of an adjacent line segment of the first fan-out trace 61, for example, intersect with both the first direction X and the second direction Y.

The display substrate provided by the present embodiment can provide a double-insurance path for signal transmission by connecting a first connection line and a second connection line in parallel between adjacent first circuit groups, so as to ensure that there is at least one transmission path, thereby effectively avoiding the yield loss of the display substrate caused by line breakage of the bonding region in the bending process.

FIG. 16 is another schematic diagram of a bonding region of a display substrate according to at least one embodiment of the present disclosure. In some examples, as shown in FIG. 16, the bonding region B1 of the display substrate may include a first fan-out region B11, a bending region B12, a second fan-out region B13, a first circuit region B14, a third fan-out region B15, a drive chip region B16, and a bonding pin region B10 sequentially disposed along a direction away from the display region AA. Adjacent first circuit groups may be electrically connected by a first connection line, thereby ensuring the consistency of signal transmission and further ensuring the uniformity of the display region. For example, the first circuit groups 41a and 41b may be electrically connected by a first connection line 51a, the first circuit groups 41b and 41c may be electrically connected by a first connection line 51b, and the first circuit groups 41c and 41d may be electrically connected by a first connection line 51c. Adjacent first circuit groups may also be electrically connected by a second connection line. For example, the first circuit groups 41a and 41b may be electrically connected by the second connection line 52a, the first circuit groups 41b and 41c may be electrically connected by the second connection line 52b, and the first circuit groups 41c and 41d may be electrically connected by the second connection line 52c. The first connection line 51a and the second connection line 52a transmitting the same signal may be connected in parallel, the first connection line 51b and the second connection line 52b transmitting the same signal may be connected in parallel, and the first connection line 51c and the second connection line 52c transmitting the same signal may be connected in parallel. Rest of the structure of the display substrate according to this embodiment may be referred to descriptions of the aforementioned embodiments, and will not be repeated here.

A display apparatus is also provided in at least one embodiment of the present disclosure, which includes the display substrate as described above. The display apparatus may be any product or component with a display function, such as a mobile phone, a tablet computer, a television, a display, a laptop computer, a digital photo frame, or a navigator.

The drawings of the present disclosure only involve structures involved in the present disclosure, and other structures may refer to conventional designs. The embodiments of the present disclosure, i.e., features in the embodiments, may be combined with each other to obtain new embodiments if there is no conflict. Those of ordinary skills in the art should understand that modifications or equivalent replacements may be made to the technical solutions of the present disclosure without departing from the spirit and scope of the technical solutions of the present disclosure, which shall all fall within the scope of the claims of the present application.

1. A display substrate, comprising:
a base substrate, comprising a display region, and a bonding region on a side of the display region;
a plurality of first circuit groups, at least one group of first connection lines and at least one group of second connection lines, that are located in the bonding region; wherein the plurality of first circuit groups are arranged along a first direction;
wherein at least two adjacent first circuit groups of the plurality of first circuit groups are electrically connected by a group of the at least one group of first connection lines and a group of the at least one group of second connection lines;
a first connection line and a second connection line, in the group of first connection lines and the group of second connection lines, transmitting a same signal are connected in parallel, and the at least one group of second connection lines is located on a side of the at least one group of first connection lines close to the display region.

2. The display substrate of claim 1, wherein two adjacent first circuit groups of the plurality of first circuit groups are electrically connected by a group of first connection lines and a group of second connection lines.

3. The display substrate of claim 1, wherein any two adjacent first circuit groups of the plurality of first circuit groups are electrically connected by a group of first connection lines and a group of second connection lines.

4. The display substrate of claim 1, wherein the bonding region comprises a first sub-region, a bending region and a second sub-region that are sequentially disposed along a direction away from the display region;
the plurality of first circuit groups and the at least one group of first connection lines are located in the second sub-region, and the at least one group of second connection lines is located in the first sub-region.

5. The display substrate of claim 4, wherein the bending region comprises a plurality of bending adapter lines, and two ends of each second connection line in a group of second connection lines are each electrically connected to a first connection line in a corresponding group of first connection lines via a bending adapter line.

6. The display substrate of claim 5, wherein in a direction perpendicular to the display substrate, the plurality of bending adapter lines are located on a side of the at least one group of first connection lines and the at least one group of second connection lines away from the base substrate.

7. The display substrate of claim 4, wherein the first sub-region further comprises a plurality groups of first fan-out traces arranged along the first direction; a group of second connection lines is disposed between two adjacent groups of first fan-out traces, and an orthographic projection of the group of second connection lines on the base substrate does not overlap with orthographic projections of the two adjacent groups of first fan-out traces on the base substrate.

8. The display substrate of claim 4, wherein at least one first connection line in a group of first connection lines comprises a first trace segment, a second trace segment, and a third trace segment that are electrically connected sequentially, the second trace segment extends in the first direction, the first trace segment is electrically connected to a first circuit group, and the third trace segment is electrically connected to another first circuit group.

9. The display substrate of claim 8, wherein the second sub-region further comprises a plurality of first electrostatic discharge circuits; the first trace segment, the second trace segment and the third trace segment of at least one first connection line in the at least one group of first connection lines are each electrically connected to a first electrostatic discharge circuit; a first electrostatic discharge circuit to which the first trace segment is electrically connected is located on a side of the first trace segment close to the third trace segment, a first electrostatic discharge circuit to which the second trace segment is electrically connected is located on a side of the second trace segment close to the bending region, and a first electrostatic discharge circuit to which the third trace segment is electrically connected is located on a side of the third trace segment close to the first trace segment.

10. The display substrate of claim 8, wherein at least one second connection line in a group of second connection lines comprises a fourth trace segment, a fifth trace segment, and a sixth trace segment that are electrically connected sequentially, the fifth trace segment extends in the first direction, the fourth trace segment and the sixth trace segment are located on a side of the fifth trace segment away from the display region, and a length of the fifth trace segment along the first direction is less than a shortest distance between a first trace segment and a third trace segment of a first connection line to which the second connection line is electrically connected.

11. The display substrate of claim 1, further comprising a buffer layer on a side of the base substrate away from the plurality of first circuit groups; an orthographic projection of the at least one group of first connection lines to which the at least one group of second connection lines is electrically connected on the base substrate partially overlaps with an orthographic projection of the buffer layer on the base substrate.

12. The display substrate of claim 1, further comprising a plurality of bonding pin groups located in the bonding region, wherein the plurality of bonding pin groups are located on a side of the plurality of first circuit groups away from the display region, and are electrically connected to the plurality of first circuit groups.

13. The display substrate of claim 12, further comprising a plurality of drive chip pin groups located in the bonding region, wherein the plurality of drive chip pin groups are located on a side of the plurality of first circuit groups away from the display region, and located on a side of the plurality of bonding pin groups close to the display region.

14. The display substrate of claim 1, wherein the display region comprises a plurality of sub-pixels and a plurality of data lines, the plurality of data lines are electrically connected to the plurality of sub-pixels;
at least one first circuit group of the plurality of first circuit groups comprises a plurality of test circuits, the plurality of test circuits are connected to the plurality of data lines and configured to provide test data signals to the plurality of data lines during a test phase.

15. A display apparatus, comprising a display substrate according to claim 1.

16. The display substrate of claim 2, wherein the bonding region comprises a first sub-region, a bending region and a second sub-region that are sequentially disposed along a direction away from the display region;
the plurality of first circuit groups and the at least one group of first connection lines are located in the second sub-region, and the at least one group of second connection lines is located in the first sub-region.

17. The display substrate of claim 3, wherein the bonding region comprises a first sub-region, a bending region and a second sub-region that are sequentially disposed along a direction away from the display region;
the plurality of first circuit groups and the at least one group of first connection lines are located in the second sub-region, and the at least one group of second connection lines is located in the first sub-region.

18. The display substrate of claim 9, wherein at least one second connection line in a group of second connection lines comprises a fourth trace segment, a fifth trace segment, and a sixth trace segment that are electrically connected sequentially, the fifth trace segment extends in the first direction, the fourth and sixth trace segments are located on a side of the fifth trace segment away from the display region, and a length of the fifth trace segment along the first direction is less than a shortest distance between a first trace segment and a third trace segment of a first connection line to which the second connection line is electrically connected.

19. The display substrate of claim 6, wherein the first sub-region further comprises a plurality groups of first fan-out traces arranged along the first direction; a group of second connection lines is disposed between two adjacent groups of first fan-out traces, and an orthographic projection of the group of second connection lines on the base substrate does not overlap with orthographic projections of the two adjacent groups of first fan-out traces on the base substrate.

20. The display substrate of claim 19, wherein at least one first connection line in a group of first connection lines comprises a first trace segment, a second trace segment, and a third trace segment that are electrically connected sequentially, the second trace segment extends in the first direction, the first trace segment is electrically connected to a first circuit group, and the third trace segment is electrically connected to another first circuit group.
